(19) United States
(12) Patent Application Publication
(10) Pub. No.: US 2019/0131520 A1
(43) Pub. Date: May 2, 2019

(54) MEMORY CELL COMPRISING A PHASE-CHANGE MATERIAL

(71) Applicant: STMicroelectronics (Crolles 2) SAS, Crolles (FR)

(72) Inventors: Pierre MORIN, Kessel-Lo (BE); Franck ARNAUD, St. Nazaire Les Eymes (FR); Didier DUTARTRE, Meylan (FR)

(73) Assignee: STMicroelectronics (Crolles 2) SAS, Crolles (FR)

(21) Appl. No.: 16/168,131

(22) Filed: Oct. 23, 2018

(30) Foreign Application Priority Data
Oct. 27, 2017 (FR) 1760164

(51) Int. Cl. H01L 45/00

(52) U.S. Cl. CPC H01L 45/06; H01L 45/128; H01L 45/126; H01L 45/16; H01L 45/1206

(57) ABSTRACT

A memory cell includes a phase-change material. A via is electrically connected with a transistor and an element for heating the phase-change material. An electrically-conductive thermal barrier is positioned between the via and the heating element.

### PRIORITY CLAIM

This application claims the priority benefit of French Application for Patent No. 1760164, filed on Oct. 27, 2017, the content of which is hereby incorporated by reference in its entirety to the maximum extent allowable by law.

### TECHNICAL FIELD

The present disclosure relates to electronic chips, and more particularly to a non-volatile memory cell comprising a phase-change material.

### BACKGROUND

In a memory cell comprising a phase-change material, the phase-change material is, for example, a crystalline chalcogenide. To program such a memory cell, the chalcogenide is heated to melt a portion thereof. After the heating has stopped, the molten portion cools down sufficiently fast to become amorphous. The erasing of the memory cell is obtained by heating the chalcogenide without melting it, so that the amorphous portion recrystallizes. The reading of the programmed or erased state of the memory cell uses the difference between the electric conductivity of the amorphous chalcogenide and that of the crystalline chalcogenide.

Known phase-change memory cells have various disadvantages, such as a need for a high current during programming, and various compactness problems. Such issues are crucial, for example, for an electronic chip comprising several millions, or even several billions, of such memory cells.

### SUMMARY

An embodiment provides overcoming all or part of the above disadvantages.

Thus, an embodiment provides a memory cell comprising a phase-change material comprising, on a via of connection with a transistor, an element for heating the phase-change material and, between the via and the heating element, an electrically-conductive thermal barrier.

According to an embodiment, the thermal barrier comprises a material more thermally insulating than that of the via.

According to an embodiment, the thermal barrier comprises a material having a thermal resistivity greater than 0.02 m⋅K/W.

According to an embodiment, the thermal barrier comprises a material selected from the group comprising: titanium nitrides; silicon and titanium nitrides; silicides; doped amorphous silicon; doped silicon-germanium; and doped amorphous germanium.

According to an embodiment, the thickness of the thermal barrier is greater than 10 nm.

According to an embodiment, the thermal barrier comprises a layer of a material forming with those of the via and of the heating element of the interfacial thermal resistors.

According to an embodiment, said interfacial thermal resistances are greater than 2×·10⁻⁹ m²⋅K/W.

According to an embodiment, the thermal barrier comprises a material selected from the group comprising: titanium nitrides; doped silicon; doped silicon-germanium; doped germanium; and graphene.

According to an embodiment, the thermal barrier comprises, in an electrically-insulating material, an electrically-conductive path obtained by breakdown.

According to an embodiment, the thermal barrier comprises two layers forming together an interfacial thermal resistor.

An embodiment provides a method of manufacturing a memory cell comprising a phase-change material, comprising: a) forming a via of connection with a transistor; b) forming on the via an element for heating the phase-change material; and c) between steps a) and b), forming a layer of an electrically-conductive material capable of forming, at step b), a thermal barrier between the via and the heating element, and/or capable of forming with the via and the heating element interfaces forming a thermal barrier.

According to an embodiment, the method further comprises: d) between steps a) and c), etching an upper portion of the via; and e) after step c), removing the portions of said layer located outside of the portion etched at step d).

### BRIEF DESCRIPTION OF THE DRAWINGS

The foregoing and other features and advantages will be discussed in detail in the following non-limiting description of specific embodiments in connection with the accompanying drawings, wherein:

FIG. 1 is a simplified cross-section view of a memory cell comprising a phase-change material;

FIG. 2 is a partial simplified cross-section view of an embodiment of a memory cell comprising a phase-change material;

FIGS. 3A to 3D are partial simplified cross-section views illustrating steps of an embodiment of a method of manufacturing a memory cell comprising a phase-change material; and

FIGS. 4A to 4D are partial simplified cross-section views illustrating steps of another embodiment of a method of manufacturing a memory cell comprising a phase-change material.

### DETAILED DESCRIPTION

The same elements have been designated with the same reference numerals in the various drawings and, further, the various drawings are not to scale. For clarity, only those steps and elements which are useful to the understanding of the described embodiments have been shown and are detailed.

In the following description, when reference is made to terms qualifying absolute positions, such as terms “high”, “low”, etc., or relative positions, such as terms “above”, “under”, “upper”, “lower”, etc., or to terms qualifying orientation, such as term “horizontal”, “vertical”, reference is made to the orientation of the concerned element in the drawings, it being understood that in practice, the described devices may be oriented differently.

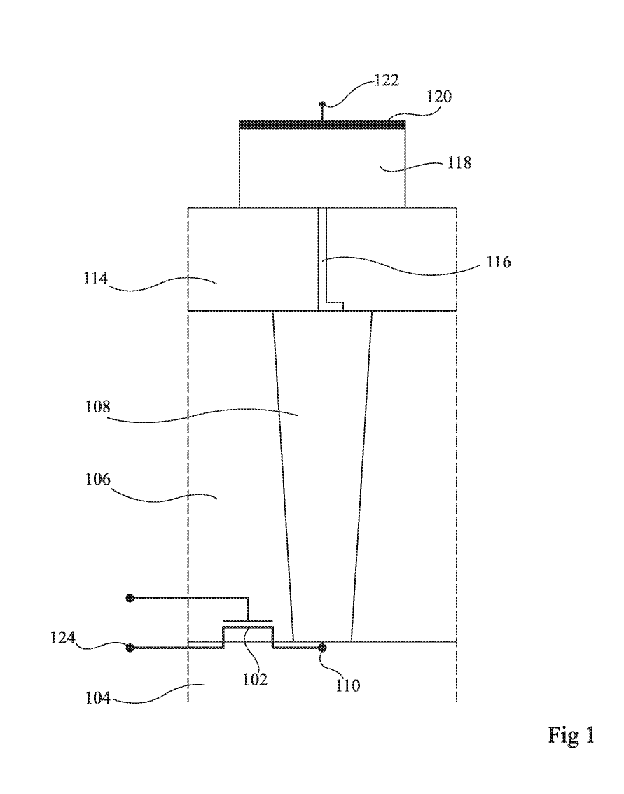

FIG. 1 is a simplified cross-section view of a memory cell comprising a phase-change material.

A transistor 102, for example, of MOS type, but which may also be of bipolar type, is formed inside and on top of a semiconductor support 104. This transistor is shown symbolically with a source, a drain and an insulated gate. Transistor 102 and support 104 are covered with an electrically-insulating layer 106, for example, made of silicon oxide. An electrically-conductive via 108, for example, made of tungsten, thoroughly crosses layer 106 and has its lower end in contact with drain 110 of transistor 102. Layer 106 and via 108 are covered with an electrically-insulating layer 114, for example, made of silicon nitride, thoroughly crossed by a resistive element 116. Resistive element 116 is arranged on via 108 and is in contact with via 108. The resistive element 116 is, for example, made of titanium silicon nitride TiSiN and typically has the shape of a wall with a thickness, for example, in the range from 2 to 10 nm, with a width, for example, greater than 15 nm and a height, for example, in the range from 30 to 150 nm. Resistive element 116 and insulating layer 114 are topped with a phase-change material 118 covered with a contacting area 120 connected to a node 122. Phase-change material 118, resistive element 116, and transistor 102 are thus electrically connected in series between node 122 and source 124 of transistor 102.

To program or erase the memory cell, the memory cell is selected by the turning-on of transistor 102 and a voltage is applied between node 122 and source 124. A current runs through the resistive element, which generates heat, and the temperature of the resistive element strongly rises. The phase change material in contact with resistive heating element 116 melts (for the programming) or recrystallizes (for the erasing).

A problem is that part of the generated heat is not used to raise the temperature of heating element 116 and thus to melt or recrystallize material 118, but is absorbed or dissipated by the materials surrounding the heating element, particularly by conductive via 108, according to the dimensions and the materials of the via. A large amount of heat then has to be generated to obtain, in the heating element, a temperature sufficient for the memory cell to be programmed or erased. This results in the issue, mentioned in the preamble, of high programming and erasing currents. Transistor 102 should have large dimensions to allow the flowing of such currents, which poses the above-mentioned compactness problems.

A memory cell with decreased programming and erasing currents is provided hereafter, which memory cell can then be particularly compact.

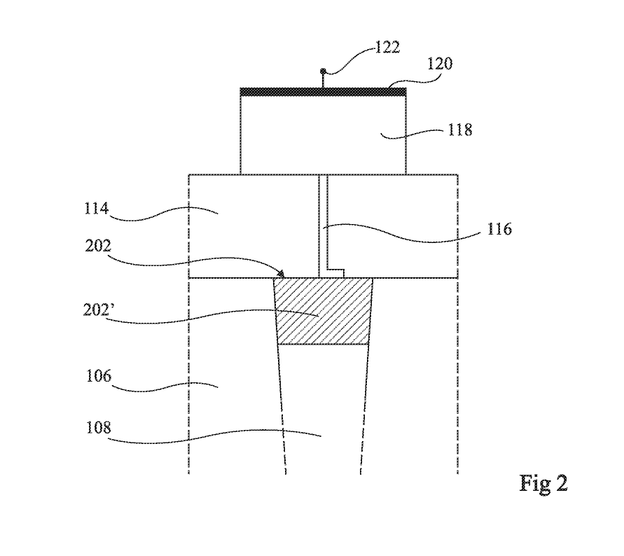

FIG. 2 is a partial simplified cross-section view of an embodiment of a memory cell. Only the upper portions of the memory cells are shown in FIG. 2 and the following. The memory cell of FIG. 2 comprises the elements of the memory cell of FIG. 1, or similar elements, arranged identically or similarly. Only the differences between the memory cells of FIGS. 1 and 2 are highlighted hereafter.

In the memory cell of FIG. 2, a thermal barrier 202 is arranged between via 108 and resistive heating element 116. As an example, via 108 does not reach the upper surface of layer 106, and the thermal barrier extends in line with the via at the upper end of the via and reaches the surface of layer 106. Barrier 202 comprises an electrically-conductive material in contact with via 108 and with heating element 116, which enables the flowing of a current, particularly a programming and erasing current, between via 108 and element 116.

The thermal barrier enables to strongly decrease losses towards via 108 of the heat generated in heating element 116. A decreased amount of generated heat is thus sufficient for the temperature of heating element 116 to strongly rise and for the memory cell to be programmed or erased. The programming and erasing currents are thus particularly decreased.

As an example, to decrease heat losses from element 116 towards via 108, the thermal barrier is made of a material which is more thermally insulating than that of the via. The thermal barrier then is, for example, made of: titanium, or titanium silicon nitride, of a silicide, or of bismuth lead tellurium; a doped amorphous semiconductor such as doped amorphous silicon or doped amorphous germanium; an alloy, for example, doped semiconductor such as doped silicon-germanium; or of a material having a thermal resistivity greater than 0.02 m⋅K/W, for example, greater than 0.1 m⋅K/W. The thermal barrier, for example, has a thickness greater than 5 nm.

As a variation, to decrease heat losses from element 116 to via 108, the thermal barrier is at least partially made of the interfaces formed by a layer 202′ with via 108 and the heating element. To achieve this, the material of layer 202′, different from those of the via and of the heating element, is selected so that these differences between materials generate, on each side of layer 202′, an interfacial thermal resistor, that is, a resistor which opposes the flowing of heat between two different materials in contact with each other. Such an interfacial resistor, for example, appears when the vibrations, or phonons, of the crystal lattices of the materials propagate differently in the two materials, and/or have different frequencies in the two materials. Phonons then tend to be reflected by the interface. The material of layer 202′ is selected so that the interfaces between this material and the materials of via 108 and of the heating element have thermal resistances for example greater than 10⁻⁸ m²⋅K/W. Layer 202′ may then have a thickness for example smaller than 10 nm, for example, in the range from 1 to 5 nm. Layer 202′ may be a two-dimensional layer such as a graphene layer. As an example, layer 202′ is made of titanium nitride, of silicon, of silicon-germanium, or of germanium, such semiconductors being sufficiently doped to be electrically conductive.

In operation, the electric current, particularly the programming and erasing current, flows from heating element 116 to via 108 through thermal barrier 202. To achieve this, it is for example provided for the barrier to have, between via 108 and element 116, a negligible electric resistance, for example, equal to less than 10% of that of element 116. This may be obtained when the electric conductivity of the material of the thermal barrier is for example greater than 2·10⁴ S/m.

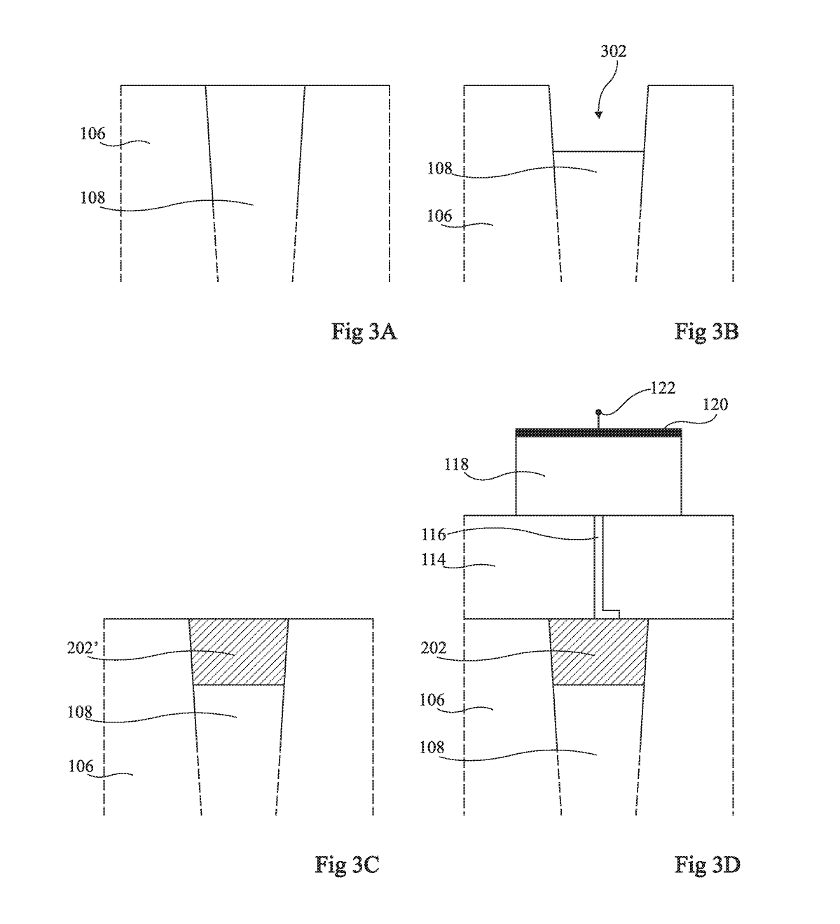

FIGS. 3A to 3D are partial simplified cross-section views illustrating successive steps of an embodiment of a method of manufacturing a memory cell comprising a phase-change material, for example, of the type in FIG. 2.

At the step of FIG. 3A, a via 108, for example, made of tungsten, connected to the drain of a transistor, not shown, has been formed in an insulating layer 106, for example, made of silicon oxide. Via 108 is flush with the upper surface of insulating layer 106, for example after a chemical-mechanical polishing (CMP).

At the step of FIG. 3B, an upper portion of via 108 is partially and selectively etched. As an example, after the etching, the upper level of via 108 is from 5 to 50 nm below that of layer 106. Via 108 is thus topped with a cavity 302.

At the step of FIG. 3C, a layer 202′ filling cavity 302 etched at step 3B is formed on the structure. Layer 202′ and/or its interfaces with the surrounding materials are intended to form the future thermal barrier 202. Layer 202′ is electrically conductive, for example, made of one of the materials described hereabove in relation with FIG. 2.

All the elements located above the upper surface of layer 106 are then removed, for example, by chemical-mechanical polishing.

At the step of FIG. 3D, the rest of the memory cell is formed, that is, an insulating layer 114 crossed by a heating element 116, insulating layer 114 being topped with a phase-change material 118 in contact with heating element 116.

A thermal barrier 202 is obtained between via 108 and heating element 116. The thermal barrier is located on via 108 and extends in line with via 108, that is, its shape in top view coincides with that of the via. The upper surface of barrier layer 202 is flush with that of layer 106.

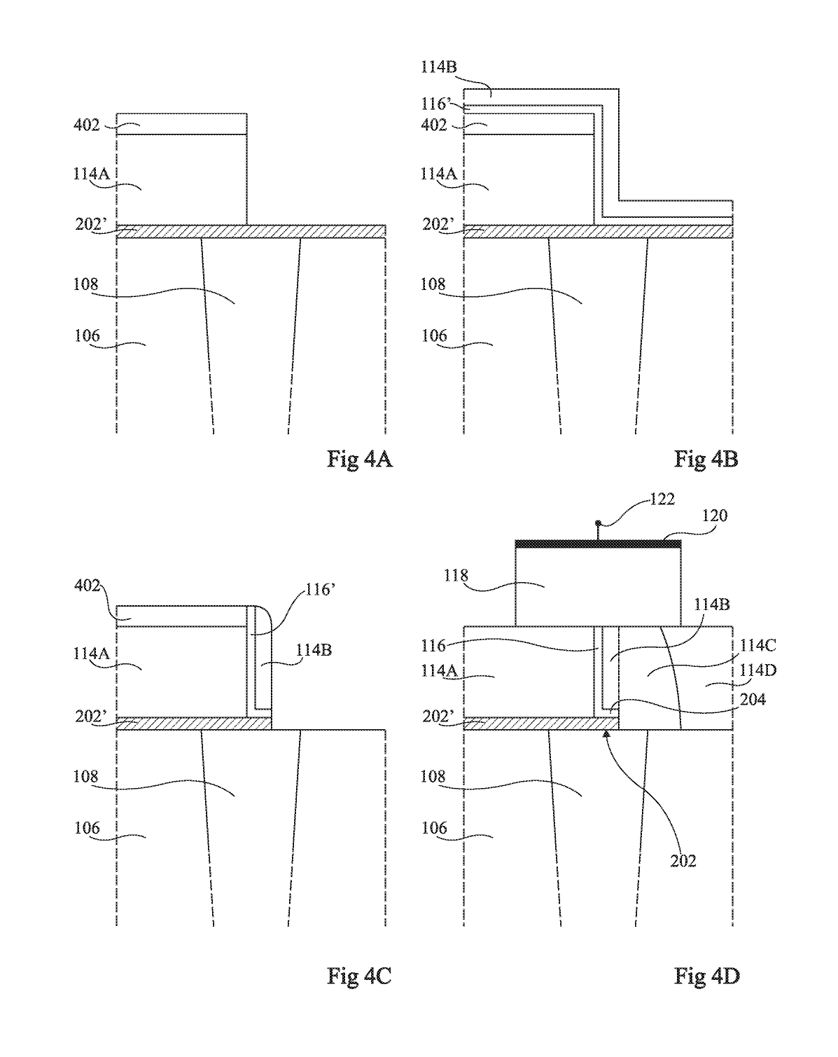

FIGS. 4A to 4D are partial simplified cross-section views illustrating steps of another embodiment of a method of manufacturing a memory cell comprising a phase-change material.

At the step of FIG. 4A, a via 108, for example, made of tungsten, connected to the drain of a transistor, not shown, has been formed in an insulating layer 106, for example, made of silicon oxide. Via 108 is flush with the upper surface of insulating layer 106, for example after a chem.-mech. polishing.

A layer 202′ is formed on the structure. Layer 202′ and/or its interfaces with the surrounding materials are intended to form the future thermal barrier. Layer 202′ is electrically conductive, for example, made of one of the materials described hereabove in relation with FIG. 2. In the case of materials forming thermal resistors of interface with the materials surrounding layer 202′, the thickness of layer 202′ may have a thickness smaller than 10 nm, or even than 1 nm. Layer 202′ may then be made of graphene. The graphene will form particularly high interfacial thermal resistances with via 108 and heating element 116, for example, for a tungsten via and a future heating element made of titanium silicon nitride.

The structure is then covered with an electrically-insulating layer 114A, for example, made of silicon nitride, and then with a layer 402, for example, made of silicon oxide. Layer 114A is a portion of a future insulating layer 114 crossed by a future resistive heating element 116. As an example, the thickness of layer 114 is in the range from 30 to 150 nm.

After this, layers 402 and 114A are etched so that a side of the remaining portions of these layers is located on via 108.

At the step of FIG. 4B, a layer 116′ and a layer 114B are successively formed on the structure. The future resistive heating element will be formed of a portion of layer 116′, layer 116′ being for example made of titanium silicon nitride. Layer 114B is electrically insulating, for example, made of silicon nitride, and has a thickness for example in the range from 10 to 50 nm.

At the step of FIG. 4C, the horizontal portions of layer 114B are removed by anisotropic etching. The accessible portions of layers 116′ and 202′ are then etched.

At the step of FIG. 4D, the deposition of an electrically-insulating layer 114C, for example, made of silicon nitride, and the etching of the horizontal portions of layer 114C are successively performed. This results in a portion of layer 114C covering the vertical remaining portion of layer 114B.

The structure is then covered with an electrically-insulating layer 114D, for example, made of silicon oxide, to fill all the space which has remained free under the upper level of layer 114A.

After this, all the elements of the structure located above the upper level of layer 114A are removed, for example, by chemical-mechanical polishing (CMP), after which a region made of a phase-change material 118, covered with a contacting area 120, is formed.

In an electrically-insulating layer 114 formed of the remaining portions of layers 114A, 114B, 114C, and 114D, a resistive element 116 for heating phase-change material 118 is thus obtained. Resistive element 116 obtained by the above-described method comprises a vertical wall and a horizontal portion 204 which extends on one side from the bottom of the wall. The thermal barrier is located between via 108 and portion 204 of heating element 116.

Specific embodiments have been described. Various alterations, modifications and improvements will occur to those skilled in the art. In particular, although the thermal barriers described in the above embodiments comprise an electrically-conductive layer 202′ made of a single material, other electrically-conductive thermal barriers, that is, comprising one or a plurality of electrically-conductive materials, are possible.

As an example, layer 202′ may comprise a plurality of stacked layers, each for example made of one of the above-described materials. Materials forming together a high interfacial thermal resistance, for example, greater than 2×⋅10⁻⁹ m²⋅K/W, preferably greater than 10⁻⁸ m²⋅K/W, are then selected for the materials of two successive layers comprised in layer 202′. The efficiency of the thermal barrier is all the greater as the number of interfaces is high. The stacked layers forming layer 202′ may then be conformally deposited in the various above-described methods.

As a variation, to obtain a barrier comprising stacked conductive layer portions in the method of FIGS. 3A to 3D, one may successively, after the step of FIG. 3C:
partially etch an upper part of the portion of layer 202′ located in portion 302 etched at step 3B;
cover the structure with an additional layer made of an electrically-conductive material filling the etched portion of layer 202′; and
remove the elements located above the upper level of layer 106.

Stacked portions of layer 202′ and of the additional layer are then obtained between via 108 and heating element 116. Preferably, the materials of layer 202′ and of the additional layer form together a high interfacial thermal resistance.

As another example, conductive layer 202′ may be obtained by forming a layer of an electrically-insulating material and then by creating a path of electrically-conductive materials between via 108 and heating element 116 through this insulating layer, for example, by breakdown of the electrically-insulating material by applying at a subsequent step a sufficiently high voltage between the via and the heating element. The electrically-insulating material is then, for example, an oxide, for example, of aluminum or hafnium, or silicon nitride.

Various embodiments with various variations have been described hereabove. It should be noted that those skilled in the art may combine various elements of these various embodiments and variations without showing any inventive step. In particular, at the step of FIG. 4A, the structure having layer 202′ formed thereon may be replaced with the structure of FIG. 3C.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. A memory cell, comprising:
a via electrically connected with a transistor;
a phase-change material;
a heating element configured to heating the phase-change material; and
positioned between the via and the heating element, an electrically-conductive thermal barrier.

2. The memory cell of claim 1, wherein the electrically-conductive thermal barrier comprises a material more thermally insulating than a material of the via.

3. The memory cell of claim 2, wherein the electrically-conductive thermal barrier comprises a material having a thermal resistivity greater than 0.02 m⋅K/W.

4. The memory cell of claim 2, wherein the electrically-conductive thermal barrier comprises a material selected from the group consisting of: titanium nitrides; titanium silicon nitrides; silicides; doped amorphous silicon; doped silicon-germanium; and doped amorphous germanium.

5. The memory cell of claim 2, wherein the thickness of the electrically-conductive thermal barrier is greater than 10 nm.

6. The memory cell of claim 1, wherein the electrically-conductive thermal barrier comprises a layer of a material forming with a material of the via and a material of the heating element interfacial thermal resistances.

7. The memory cell of claim 6, wherein the interfacial thermal resistances are greater than 2×⋅10⁻⁹ m²⋅K/W.

8. The memory cell of claim 6, wherein the electrically-conductive thermal barrier comprises a material selected from the group consisting of: titanium nitrides; doped silicon; doped silicon-germanium; doped germanium; and graphene.

9. The memory cell of claim 6, wherein the electrically-conductive thermal barrier comprises, in an electrically-insulating material, an electrically-conductive path obtained by breakdown.

10. The memory cell of claim 1, wherein the electrically-conductive thermal barrier comprises two layers forming together an interfacial thermal resistor.

11. A method of manufacturing a memory cell comprising a phase-change material, comprising:
a) forming a via in electrical connection with a transistor;
b) forming on the via a heating element for heating the phase-change material; and
c) between steps a) and b), forming a layer made of an electrically-conductive material capable of forming at least one of:
a thermal barrier between the via and the heating element, and
interfaces forming a thermal barrier with the via and the heating element.

12. The method of claim 11, further comprising:
d) between steps a) and c), etching an upper portion of the via; and
e) after step c), removing the portions of said layer located outside of the portion etched at step d).

13. A memory cell, comprising:
a first insulating layer having a top surface;
a via extending through the first insulating layer and connected to a transistor, said via having a top surface below the top surface of the first insulating layer;
an electrically-conductive thermal barrier filling an opening between the top surface of the via and the top surface of the first insulating layer;
a second insulating layer over said electrically-conductive thermal barrier;
a phase-change material over said second insulating layer; and
a heating element extending through said second insulating layer between the electrically-conductive thermal barrier and the phase-change material.

14. The memory cell of claim 13, wherein the electrically-conductive thermal barrier comprises a material more thermally insulating than a material of the via.

15. The memory cell of claim 14, wherein the electrically-conductive thermal barrier comprises a material having a thermal resistivity greater than 0.02 m⋅K/W.

16. The memory cell of claim 14, wherein the electrically-conductive thermal barrier comprises a material selected from the group consisting of: titanium nitrides; titanium silicon nitrides; silicides; doped amorphous silicon; doped silicon-germanium; and doped amorphous germanium.

17. The memory cell of claim 14, wherein the electrically-conductive thermal barrier comprises a material selected from the group consisting of: titanium nitrides; doped silicon; doped silicon-germanium; doped germanium; and graphene.

18. A memory cell, comprising:
a first insulating layer having a top surface;
a via extending through the first insulating layer and connected to a transistor, said via having a top surface coplanar with the top surface of the first insulating layer;
an electrically-conductive thermal barrier layer on the coplanar top surfaces;
a second insulating layer over said electrically-conductive thermal barrier layer;
a phase-change material over said second insulating layer; and
a heating element extending through said second insulating layer between the electrically-conductive thermal barrier layer and the phase-change material.

19. The memory cell of claim 18, wherein the electrically-conductive thermal barrier layer comprises a material more thermally insulating than a material of the via.

20. The memory cell of claim 19, wherein the electrically-conductive thermal barrier layer comprises a material having a thermal resistivity greater than 0.02 m⋅K/W.

21. The memory cell of claim 19, wherein the electrically-conductive thermal barrier layer comprises a material selected from the group consisting of: titanium nitrides; titanium silicon nitrides; silicides; doped amorphous silicon; doped silicon-germanium; and doped amorphous germanium.

22. The memory cell of claim 19, wherein the electrically-conductive thermal barrier layer comprises a material selected from the group consisting of: titanium nitrides; doped silicon; doped silicon-germanium; doped germanium; and graphene.
